(19) United States
(12) Patent Application Publication
(10) Pub. No.: US 2026/0372213 A1
(43) Pub. Date: Nov. 19, 2026

(54) SEMICONDUCTOR PACKAGE STRUCTURE AND METHOD FOR FORMING THE SAME

(71) Applicant: Taiwan Semiconductor Manufacturing Company, Ltd., Hsinchu (TW)

(72) Inventors: Jui-Shen CHANG, Taichung City (TW); Chung-Yu CHIU, Hsinchu City (TW); Chang-Jung HSUEH, Taipei (TW); Chen-Nan CHIU, Hsinchu City (TW); Yao-Chun CHUANG, Hsinchu City (TW)

(21) Appl. No.: 19/210,151

(22) Filed: May 16, 2025

(51) Int. Cl. H10W 90/00; H10W 70/66; H10W 70/63; H10W 74/10

(52) U.S. Cl. CPC H10W 90/701; H10W 70/66; H10W 70/635; H10W 74/111; H10W 90/00

(57) ABSTRACT

A semiconductor package structure is provided, which includes a redistribution substrate, a first semiconductor device disposed on a first side of the redistribution substrate, first connection elements disposed on a second side of the redistribution substrate opposite from the first side, and overlapping the first semiconductor device in a top view, and second connection elements disposed on the second side. The first semiconductor device includes a substrate disposed over the redistribution substrate, a semiconductor die disposed over the substrate, and an encapsulant disposed over the substrate. A first portion of the second connection elements is offset from the first semiconductor device in the top view, the first connection elements are surrounded by the second connection elements in the top view, and each first connection element has a higher electrical conductivity than each second connection element.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1O illustrate cross-sectional views of intermediate stages in the manufacturing of a semiconductor package structure in accordance with some embodiments.

FIG. 1P is a top view showing some elements of the semiconductor package structure, in accordance with some embodiments.

FIG. 2A is a cross-sectional view of a semiconductor package structure, in accordance with some embodiments.

FIG. 2B is a top view of the structure shown in FIG. 2A, in accordance with some embodiments.

FIG. 3A is an enlarged view of one of the first connection elements, in accordance with some embodiments.

FIG. 3B is an enlarged view of the second connection element, in accordance with some embodiments.

FIG. 4A is an enlarged view of the first connection element, in accordance with other embodiments of the present disclosure.

FIG. 4B is an enlarged view of the first connection element, in accordance with other embodiments of the present disclosure.

FIG. 4C is an enlarged view of the first connection elements with different pitches, in accordance with other embodiments of the present disclosure.

FIG. 5A is an enlarged view of the first connection element, in accordance with other embodiments of the present disclosure.

FIG. 5B shows the material composition along the line A-A’ in FIG. 5A, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Use of ordinal terms such as “first”, “second”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

The terms “about” and “substantially” typically mean +/- 20 % of the stated value, more typically +/- 10 % of the stated value, more typically +/- 5 % of the stated value, more typically +/- 3 % of the stated value, more typically +/- 2 % of the stated value, more typically +/- 1 % of the stated value and even more typically +/- 0.5 % of the stated value. The stated value of the present disclosure is an approximate value. When there is no specific description, the stated value includes the meaning of “about” or “substantially”.

Embodiments of the present disclosure provide semiconductor package structures having bumps with metallic cores and crystalline-type pads corresponding to the bumps. This configuration reduces the formation of intermetallic compounds between the bump and pad to mitigate crack issues, and enhances the overall reliability of semiconductor package structure.

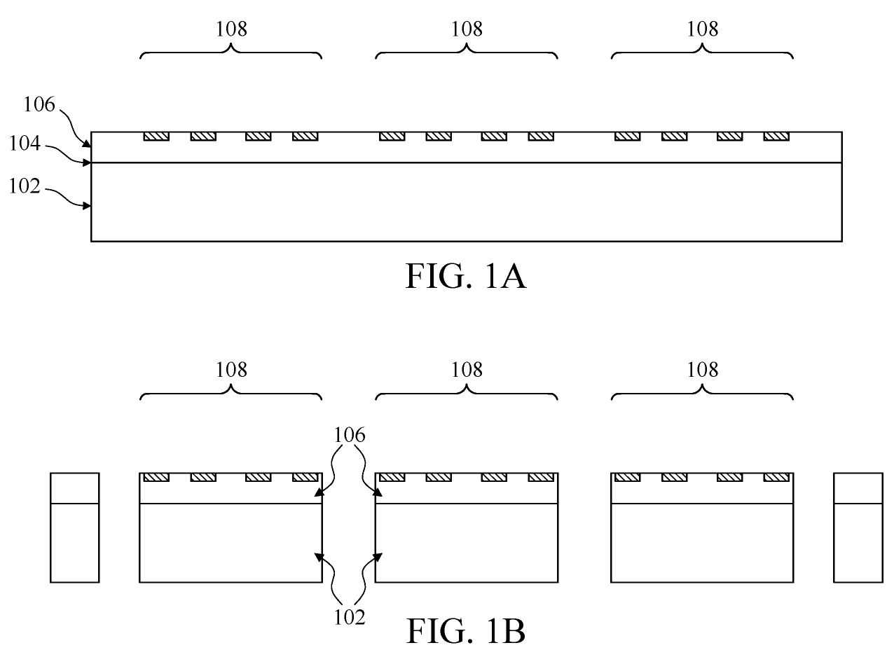

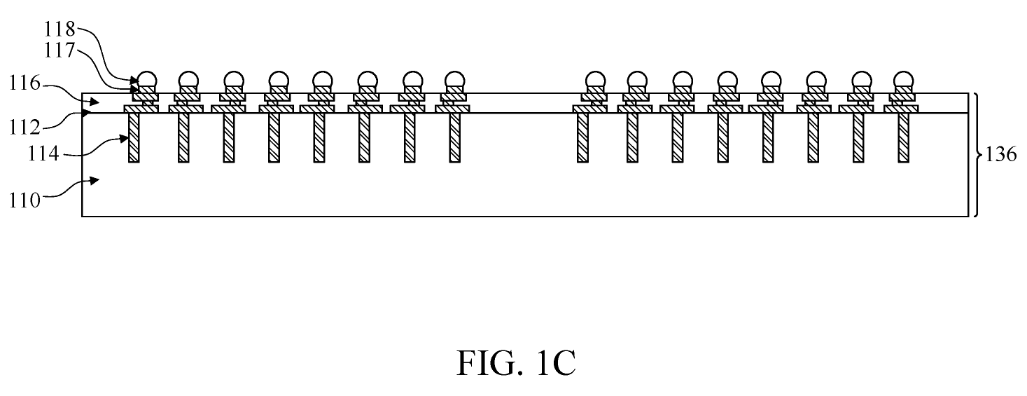

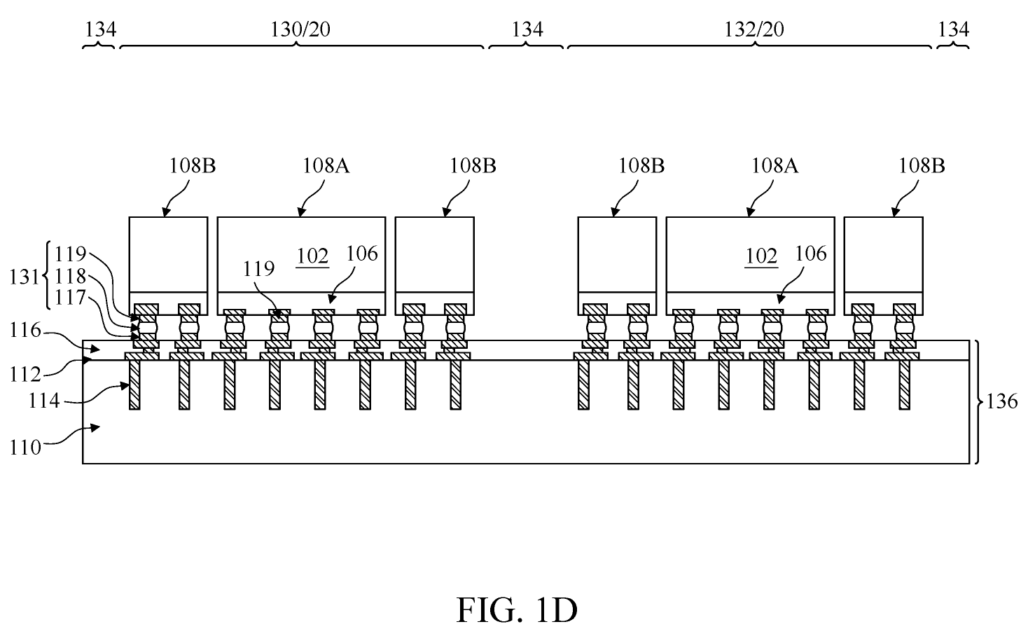

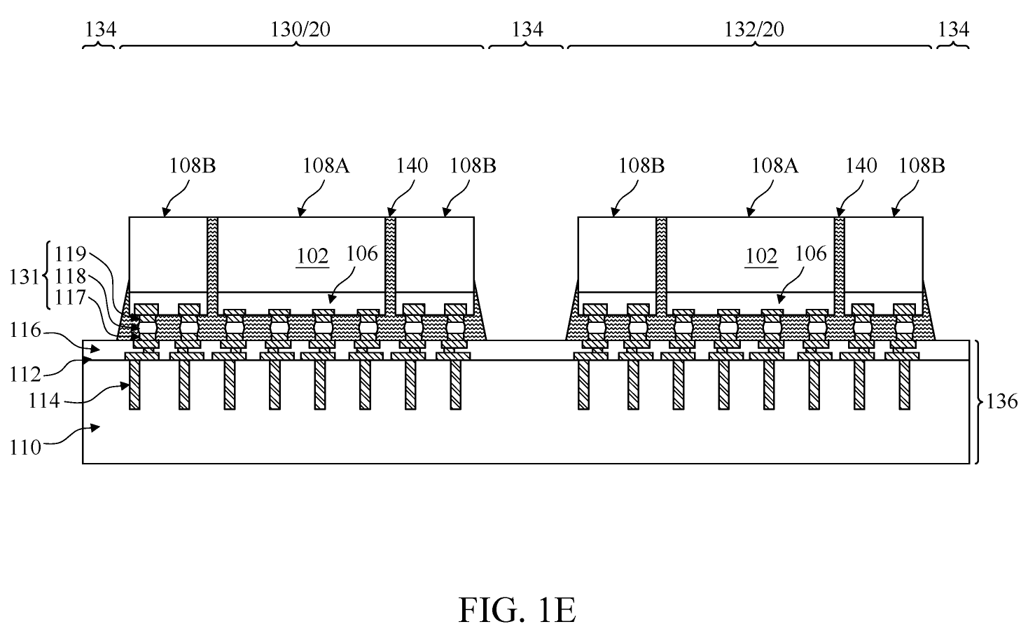

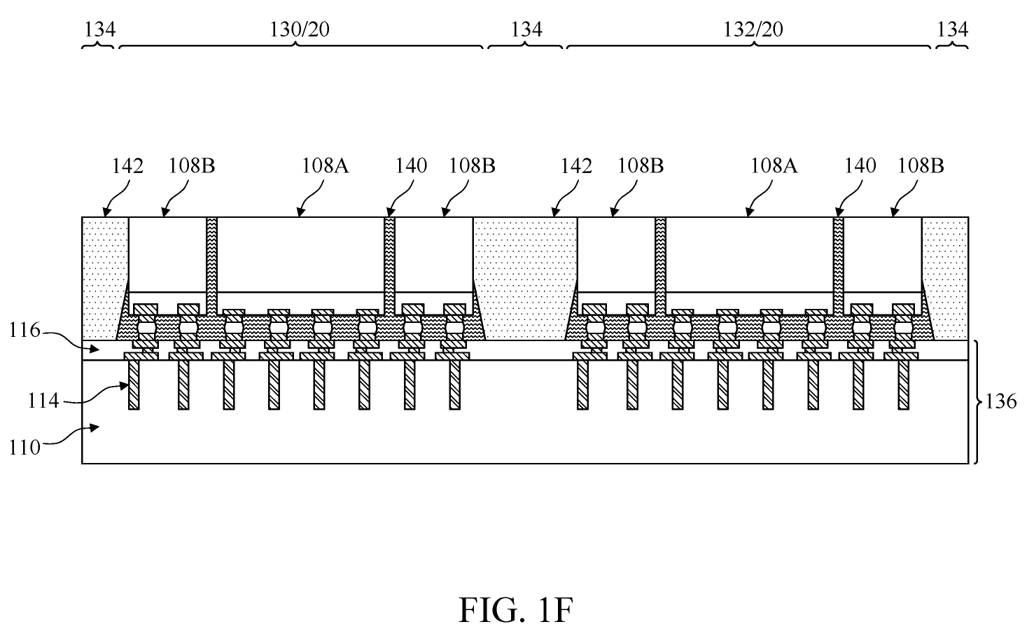

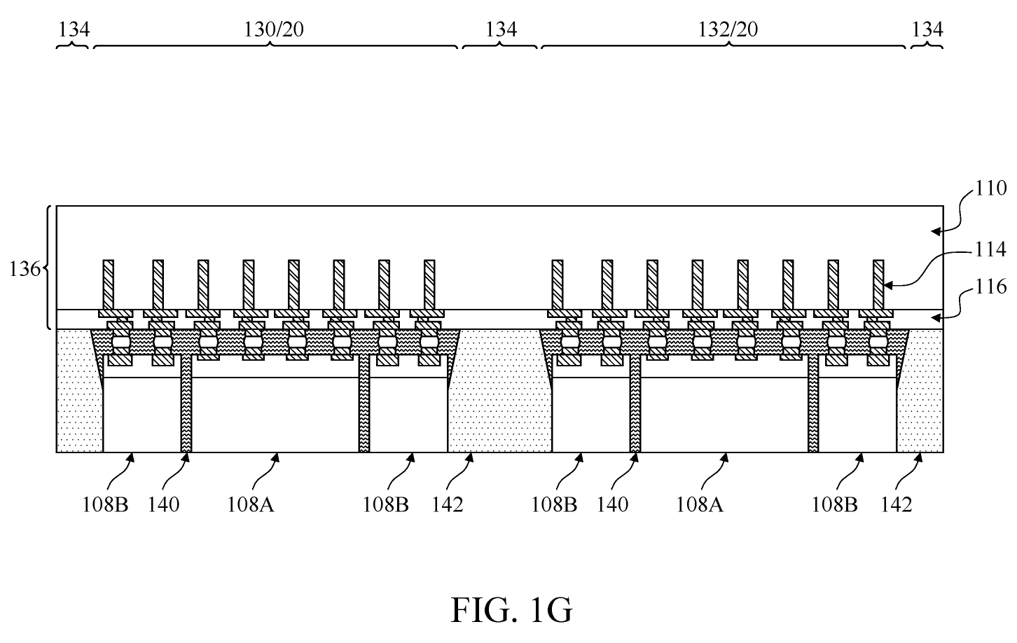

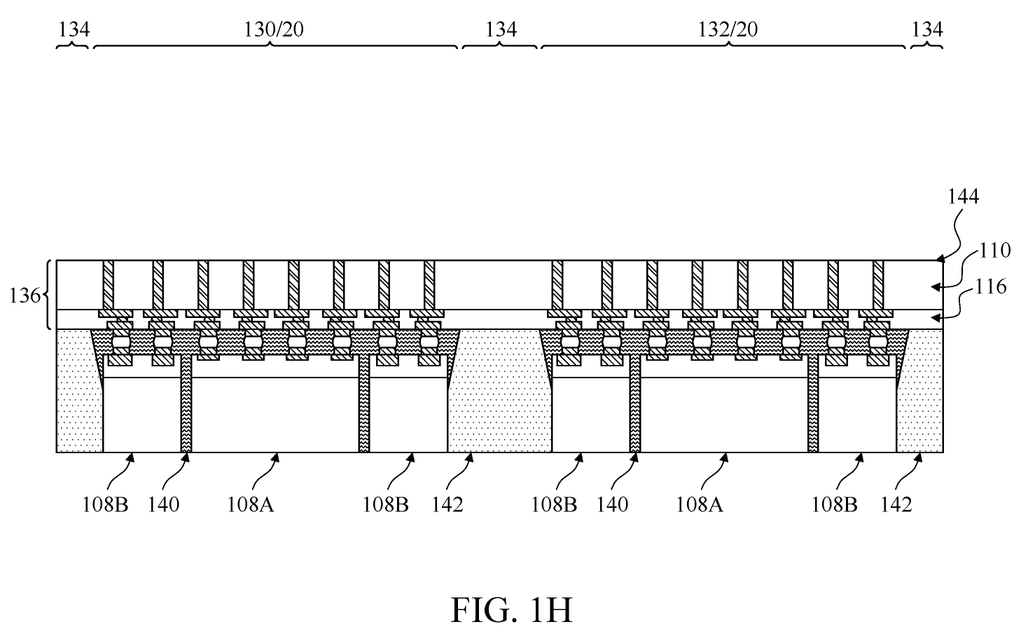

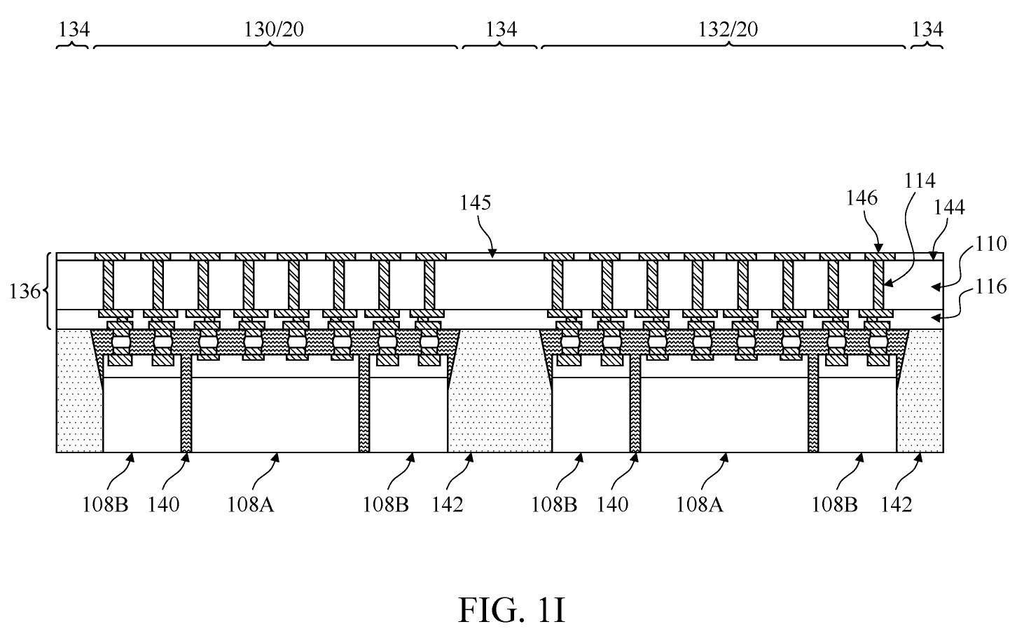

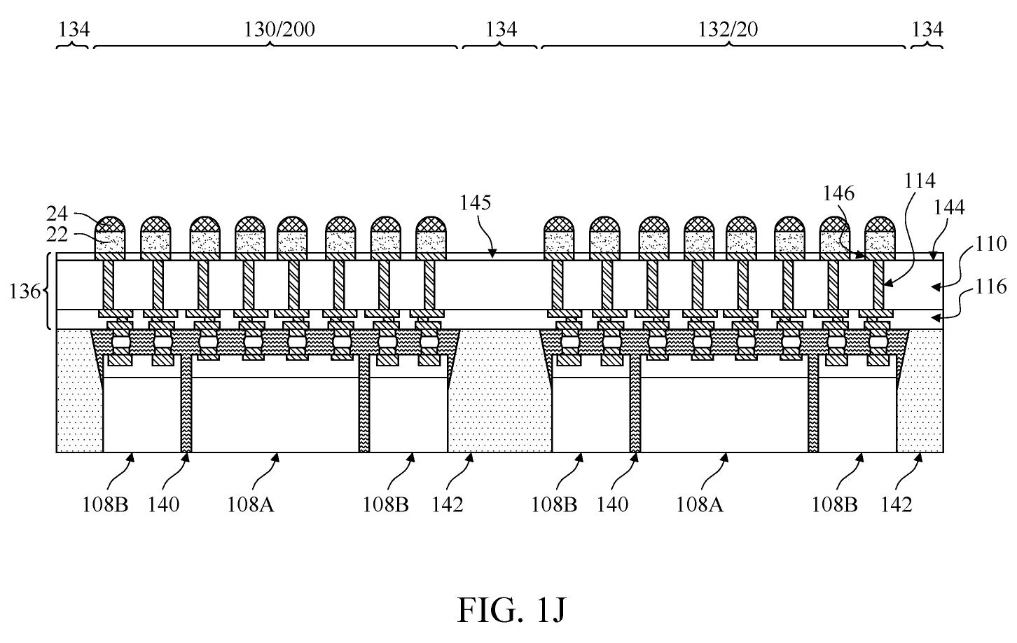

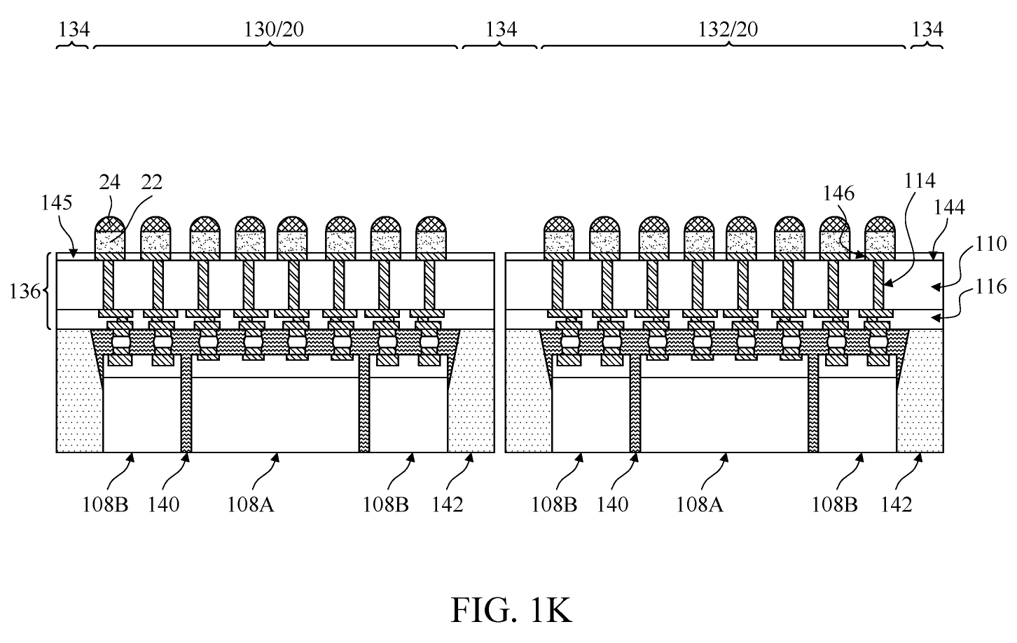

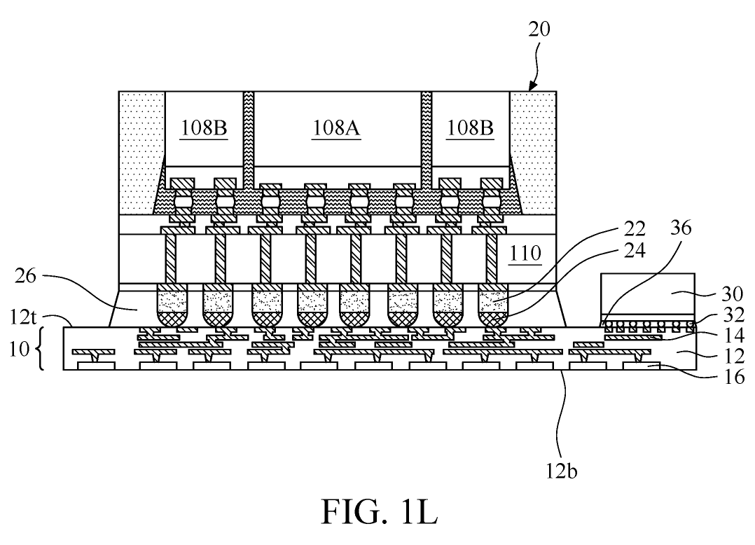

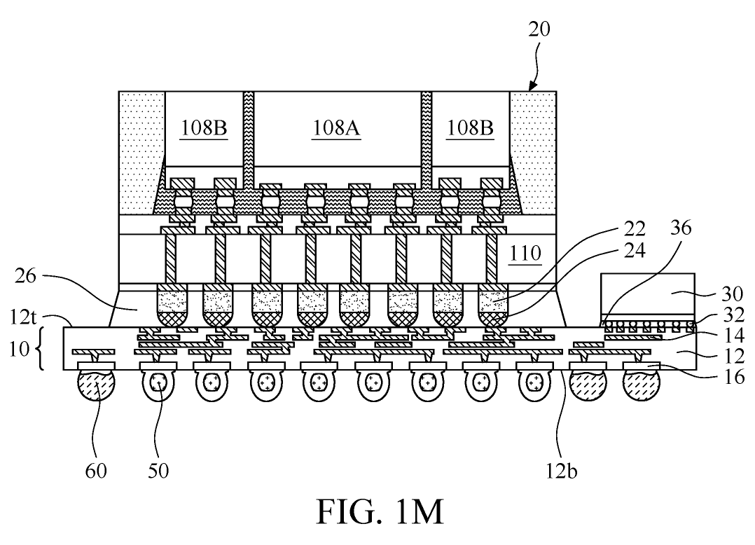

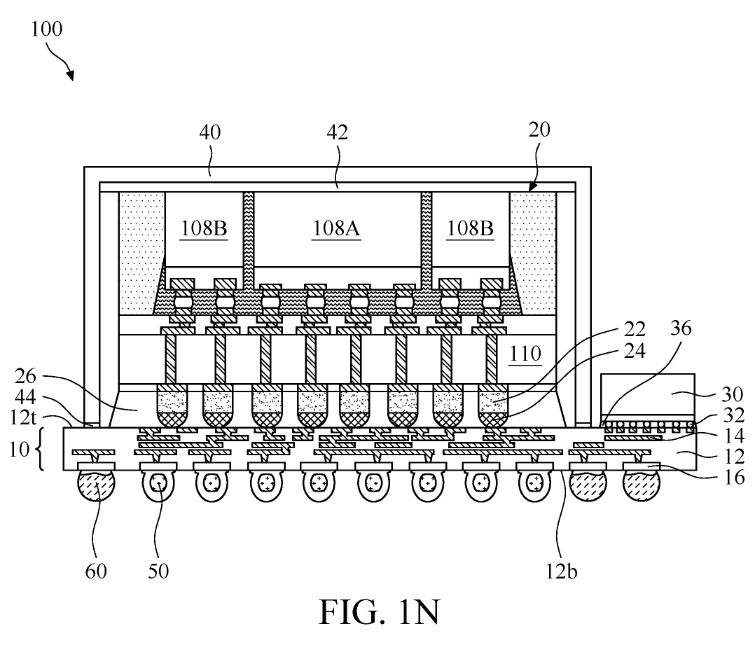

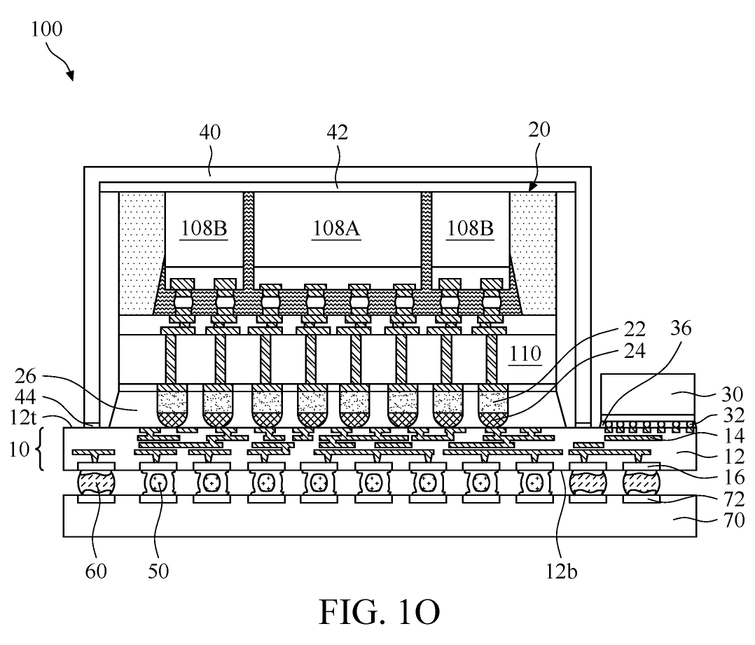

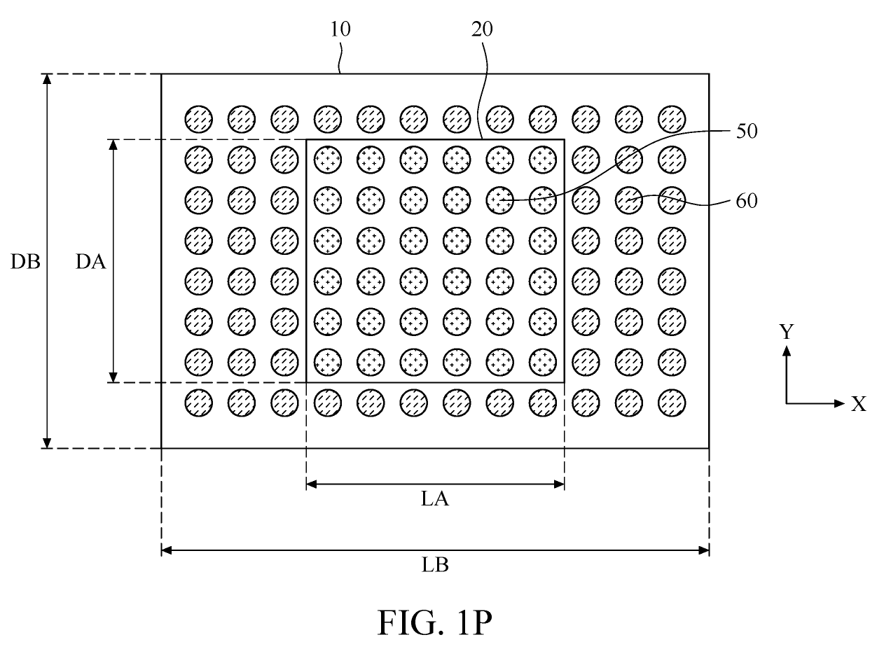

FIG. 1A to FIG. 1O illustrate cross-sectional views of intermediate stages in the manufacturing of a semiconductor package structure 100 in accordance with some embodiments. FIG. 1A illustrates one or more semiconductor dies 108. A main body 102 of the semiconductor dies 108 may comprise any number of dies, substrates, transistors, active devices, passive devices, or the like. In an embodiment, the main body 102 may include a bulk semiconductor substrate, semiconductor-on-insulator (SOI) substrate, multi-layered semiconductor substrate, or the like. The semiconductor material of the main body 102 may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The main body 102 may be doped or undoped. Devices, such as transistors, capacitors, resistors, diodes, and the like, may be formed in and/or on an active surface 104 of the main body 102.

An interconnect structure 106 comprising one or more dielectric layer(s) and respective metallization pattern(s) is formed on the active surface 104. The metallization pattern(s) in the dielectric layer(s) may route electrical signals between the devices, such as by using vias and/or traces, and may also contain various electrical devices, such as capacitors, resistors, inductors, or the like. The various devices and metallization patterns may be interconnected to form integrated circuits that perform one or more functions. The integrated circuits may include memories, processors, sensors, amplifiers, power distribution devices, input/output circuitry, or the like. Additionally, die connectors, such as conductive pillars (for example, comprising a metal such as copper), are formed in and/or on the interconnect structure 106 to provide an external electrical connection to the circuitry and devices.

As an example to form a layer of the interconnect structure 106, an inter-metallization dielectric (IMD) layer may be formed. The IMD layer may be formed, for example, of a low-K dielectric material, such as phosphosilicate glass (PSG), borophosphosilicate glass (BPSG), fluorosilicate glass (FSG), SiOₓC_{y}, Spin-On-Glass, Spin-On-Polymers, silicon carbon material, compounds thereof, composites thereof, combinations thereof, or the like, by any suitable method, such as spinning, chemical vapor deposition (CVD), plasma-enhanced CVD (PECVD), high-density plasma chemical vapor deposition (HDP-CVD), or the like. A metallization pattern may be formed in the IMD layer, for example, by using photolithography techniques to deposit and pattern a photoresist material on the IMD layer to expose portions of the IMD layer that are to become the metallization pattern. An etch process, such as an anisotropic dry etch process, may be used to create recesses and/or openings in the IMD layer corresponding to the exposed portions of the IMD layer. The recesses and/or openings may be lined with a diffusion barrier layer and filled with a conductive material. The diffusion barrier layer may comprise one or more layers of tantalum nitride, tantalum, titanium nitride, titanium, cobalt tungsten, the like, or a combination thereof, deposited by atomic layer deposition (ALD), or the like. The conductive material of the metallization patterns may comprise copper, aluminum, tungsten, silver, and combinations thereof, or the like, deposited by CVD, physical vapor deposition (PVD), or the like. Any excessive diffusion barrier layer and/or conductive material on the IMD layer may be removed, such as by using a chemical mechanical polish (CMP). Additional layers of the interconnect structure 106 may be formed by repeating these steps.

In FIG. 1B, the main body 102 including the interconnect structure 106 is singulated into individual semiconductor dies 108. Typically, each of the semiconductor dies 108 contains the same circuitry, such as the same devices and metallization patterns, although some or all of the semiconductor dies 108 may have different circuitry. The singulation may include sawing, dicing, or the like.

In some embodiments, the semiconductor dies 108 may include logic dies (e.g., central processing unit, graphics processing unit, system-on-a-chip, field-programmable gate array (FPGA), microcontroller, or the like), memory dies (e.g., dynamic random access memory (DRAM) die, static random access memory (SRAM) die, or the like), power management dies (e.g., power management integrated circuit (PMIC) die), radio frequency (RF) dies, sensor dies, micro-electro-mechanical-system (MEMS) dies, signal processing dies (e.g., digital signal processing (DSP) die), front-end dies (e.g., analog front-end (AFE) dies), the like, or a combination thereof. Also, in some embodiments, the semiconductor dies 108 may be different sizes (e.g., different heights and/or surface areas), and in other embodiments, the semiconductor dies 108 may be the same size (e.g., same heights and/or surface areas).

FIG. 1C illustrates one or more components 136 during processing, in accordance with some embodiments. The components 136 may be interposers or other dies. A substrate 110 may form the main body of the components 136. The substrate 110 can be a wafer. The substrate 110 may comprise a bulk semiconductor substrate, SOI substrate, multi-layered semiconductor substrate, or the like. The semiconductor material of the substrate 110 may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The substrate 110 may be doped or undoped. Devices, such as transistors, capacitors, resistors, diodes, and the like, may (or may not) be formed in and/or on a first surface 112, which may also be referred to as an active surface, of the substrate 110. In embodiments where the components 136 are interposers, the components 136 will generally not include active devices therein, although the interposer may include passive devices formed in and/or on a first surface 112. In such embodiments, the components 136 may be free of any active devices on the substrate 110.

Through-vias (TVs) 114 are formed to extend from the first surface 112 of the substrate 110 into the substrate 110. The TVs 114 are also sometimes referred to as through-substrate vias, or through-silicon vias when substrate 110 is a silicon substrate. The TVs 114 may be formed by forming recesses in the substrate 110 by, for example, etching, milling, laser techniques, a combination thereof, and/or the like. A thin barrier layer may be conformally deposited over the front side of the substrate 110 and in the recesses, such as by CVD, ALD, PVD, thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material may be deposited over the thin barrier layer and in the recesses. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer is removed from the front side of the substrate 110 by, for example, CMP. Thus, the TVs 114 may comprise a conductive material and a thin barrier layer between the conductive material and the substrate 110.

Interconnect structure 116 is formed over the first surface 112 of the substrate 110, and is used to electrically connect the integrated circuit devices, if any, and/or TVs 114 together and/or to external devices. The Interconnect structure 116 may include one or more dielectric layer(s) and respective metallization pattern(s) in the dielectric layer(s). The metallization patterns may comprise vias and/or traces to interconnect any devices and/or TVs 114 together and/or to an external device. The dielectric layers may comprise silicon oxide, silicon nitride, silicon carbide, silicon oxynitride, low-K dielectric material, such as PSG, BPSG, FSG, SiOxCy, Spin-On-Glass, Spin-On-Polymers, silicon carbon material, compounds thereof, composites thereof, combinations thereof, or the like. The dielectric layers may be deposited by any suitable method, such as spinning, CVD, PECVD, HDP-CVD, or the like. A metallization pattern may be formed in the dielectric layer, for example, by using photolithography techniques to deposit and pattern a photoresist material on the dielectric layer to expose portions of the dielectric layer that are to become the metallization pattern. An etch process, such as an anisotropic dry etch process, may be used to create recesses and/or openings in the dielectric layer corresponding to the exposed portions of the dielectric layer. The recesses and/or openings may be lined with a diffusion barrier layer and filled with a conductive material. The diffusion barrier layer may comprise one or more layers of TaN, Ta, TiN, Ti, CoW, or the like, deposited by ALD, or the like, and the conductive material may comprise copper, aluminum, tungsten, silver, and combinations thereof, or the like, deposited by CVD, PVC, or the like. Any excessive diffusion barrier layer and/or conductive material on the dielectric layer may be removed, such as by using a CMP, in accordance with some embodiments.

Electrical connectors 117/118 are formed at the top surface of the Interconnect structure 116 on conductive pads that are formed in the dielectric layers of the Interconnect structure 116. In some embodiments, the electrical connectors 117/118 include metal pillars 117 with metal cap layers 118, which may be solder caps, over the metal pillars 117. The electrical connectors 117/118 (including the metal pillars 117 and the metal cap layers 118) are sometimes referred to as micro bumps 117/118. In some embodiments, the metal pillars 117 include a conductive material such as copper, aluminum, gold, nickel, palladium, the like, or a combination thereof and may be formed by sputtering, printing, electro plating, electroless plating, CVD, or the like. The metal pillars 117 may be solder-free and have substantially vertical sidewalls. In some embodiments, respective metal cap layers 118 are formed on the respective top surfaces of the metal pillars 117. The metal cap layers 118 may include nickel, tin, tin-lead, gold, copper, silver, palladium, indium, nickel-palladium-gold, nickel-gold, the like, or a combination thereof and may be formed by a plating process.

In another embodiment, the electrical connectors 117/118 do not include the metal pillars and are solder balls and/or bumps, such as controlled collapse chip connection (C4), electroless nickel immersion Gold (ENIG), electroless nickel electroless palladium immersion gold technique (ENEPIG) formed bumps, or the like. In such embodiments, the bump electrical connectors 117/118 may include a conductive material such as solder, copper, aluminum, gold, nickel, silver, palladium, tin, the like, or a combination thereof. The electrical connectors 117/118 may be formed by initially forming a layer of solder through methods such as evaporation, electroplating, printing, solder transfer, ball placement, or the like. Once a layer of solder has been formed on the structure, a reflow may be performed in order to shape the material into the desired bump shapes.

In FIG. 1D, semiconductor dies 108 (including semiconductor dies 108A and semiconductor dies 108B) are attached to the first side of the components 136, for example, through flip-chip bonding by way of the electrical connectors 117/118 and metal pillars 119 on the dies to form conductive joints 131. The metal pillars 119 may be similar to the metal pillars 117 and their description is not repeated herein. The semiconductor dies 108 may be placed on the electrical connectors 117/118 using, for example, a pick-and-place tool. In some embodiments, the metal cap layers 118 are formed on the metal pillars 117 (as shown in FIG. 1C), the metal pillars 119 of the semiconductor dies 108, or both.

The semiconductor dies 108A and the semiconductor dies 108B may be different types of dies. In some embodiments, the semiconductor dies 108A include logic dies (e.g., central processing unit, graphics processing unit, system-on-a-chip, field-programmable gate array (FPGA), microcontroller, or the like), memory dies (e.g., dynamic random access memory (DRAM) die, static random access memory (SRAM) die, or the like), power management dies (e.g., power management integrated circuit (PMIC) die), radio frequency (RF) dies, sensor dies, micro-electro-mechanical-system (MEMS) dies, signal processing dies (e.g., digital signal processing (DSP) die), front-end dies (e.g., analog front-end (AFE) dies), the like, or a combination thereof. In some embodiments, the semiconductor dies 108A are system-on-a-chip (SoC) or graphics processing units (GPUs) and the semiconductor dies 108B are memory dies that are utilized by the semiconductor dies 108A.

In some embodiments, the semiconductor dies 108B include one or more memory dies, such as a stack of memory dies (e.g., DRAM dies, SRAM dies, High-Bandwidth Memory (HBM) dies, Hybrid Memory Cubes (HMC) dies, or the like). In the embodiments utilizing a stack of memory dies, a semiconductor die 108B can include both memory dies and a memory controller, such as, for example, a stack of four or eight memory dies with a memory controller. Also, in some embodiments, the semiconductor dies 108B may be different sizes (e.g., different heights and/or surface areas) from the semiconductor dies 108A, and in other embodiments, the semiconductor dies 108B may be the same size (e.g., same heights and/or surface areas) as the semiconductor dies 108A. In some embodiments of the present disclosure, the semiconductor dies 108B may have similar heights to those of the semiconductor dies 108A (as shown in FIG. 1D). Alternatively, the semiconductor dies 108A and 108B may have different heights in some embodiments.

The conductive joints 131 electrically couple the circuits in the semiconductor dies 108, through the interconnect structures 106, to the interconnect structure 116 and the TVs 114 of the components 136. Additionally, the Interconnect structure 116 electrically interconnects the semiconductor dies 108A and the semiconductor dies 108B to each other.

In some embodiments, before bonding the electrical connectors 117/118, the electrical connectors 117/118 are coated with a flux (not shown), such as a no-clean flux. The electrical connectors 117/118 may be dipped in the flux or the flux may be jetted onto the electrical connectors 117/118. In another embodiment, the flux may also be applied to the electrical connectors 119/118. In some embodiments, the electrical connectors 117/118 and/or 119/118 may have an epoxy flux (not shown) formed thereon before they are reflowed, with at least some of the epoxy portion of the epoxy flux remaining after the semiconductor dies 108 are attached to the components 136. This remaining epoxy portion may act as an underfill to reduce stress and protect the joints resulting from the reflowing the electrical connectors 117/118/119.

The bonding between the semiconductor dies 108 and the components 136 may be a solder bonding or a direct metal-to-metal (such as a copper-to-copper or tin-to-tin) bonding. In an embodiment, the semiconductor dies 108 are bonded to the components 136 by a reflow process. During this reflow process, the electrical connectors 117/118/119 are in contact to physically and electrically couple the semiconductor dies 108 to the components 136, in accordance with some embodiments. After the bonding process, an IMC (not shown) may form at the interface of the metal pillars 117/119 and the metal cap layers 118.

In FIG. 1D and subsequent figures, a first package region 130 and a second package region 132 for the formation of a first integrated circuit package and a second integrated circuit package, respectively, are illustrated. Scribe line regions 134 are between adjacent package regions. As illustrated in FIG. 1D, a single semiconductor die 108A and multiple semiconductor dies 108B are attached in each of the first package region 130 and the second package region 132.

In FIG. 1E, an underfill material 140 is dispensed into the gaps between the semiconductor dies 108 and the interconnect structure 116. In addition, the underfill material may be dispensed into the gaps between sidewalls of adjacent semiconductor dies 108. The underfill material 140 extends up along sidewall of the semiconductor dies 108A and the semiconductor dies 108B. The underfill material 140 may be any acceptable material, such as a polymer, epoxy, molding underfill, or the like. The underfill material 140 may be formed by a capillary flow process after the semiconductor dies 108 are attached, or may be formed by a suitable deposition method before the semiconductor dies 108 are attached.

In FIG. 1F, an encapsulant 142 is formed on the various components. The encapsulant 142 may be a molding compound, epoxy, or the like, and may be applied by compression molding, transfer molding, or the like. A curing step is performed to cure the encapsulant 142, such as a thermal curing, an Ultra-Violet (UV) curing, or the like. In some embodiments, the semiconductor dies 108 are buried in the encapsulant 142, and after the curing of the encapsulant 142, a planarization step, such as a grinding, may be performed to remove excess portions of the encapsulant 142, which excess portions are over top surfaces of the semiconductor dies 108. Accordingly, top surfaces of semiconductor dies 108 are exposed, and are level with a top surface of the encapsulant 142. In some embodiments, the semiconductor dies 108B may be different heights from the semiconductor dies 108A, and the semiconductor dies 108B are still covered by the encapsulant 142 after the planarization step.

FIG. 1G to FIG. 1J illustrate processing of the second side of components 136. In FIG. 1G, the structure of FIG. 1F is flipped over to prepare for the formation of the second side of components 136. Although not shown, the structure may be placed on carrier or support structure for the process of FIG. 1G to FIG. 1J.

In FIG. 1H, a thinning process is performed on the second side of the substrate 110 to thin the substrate 110 until TVs 114 are exposed. The thinning process may include an etching process, a grinding process, the like, or a combination thereof, applied to a second surface 144 of the substrate 110.

In FIG. 1I, a redistribution structure is formed on the second surface 144 of the substrate 110, and will be used to electrically connect the TVs 114 to external devices. The redistribution structure includes a dielectric layer 145 and metallization patterns 146 in and/or on the dielectric layer 145. The metallization patterns may comprise vias and/or traces to interconnect TVs 114 together and/or to an external device. The metallization patterns 146 are sometimes referred to as Redistribution Lines (RDLs). The dielectric layer 145 may comprise silicon oxide, silicon nitride, silicon carbide, silicon oxynitride, low-K dielectric material, such as PSG, BPSG, FSG, SiOₓC_{y}, Spin-On-Glass, Spin-On-Polymers, silicon carbon material, compounds thereof, composites thereof, combinations thereof, or the like. The dielectric layer 145 may be deposited by any suitable method, such as spinning, CVD, PECVD, HDP-CVD, or the like.

The metallization patterns 146 may be formed in the dielectric layer 145, for example, by using photolithography techniques to deposit and pattern a photoresist material on the dielectric layer 145 to expose portions of the dielectric layer 145 that are to become the metallization patterns 146. An etch process, such as an anisotropic dry etch process, may be used to create openings in the dielectric layer 145 corresponding to the exposed portions of the dielectric layer 145. A seed layer (not separately illustrated) is formed over the exposed surfaces of the dielectric layer 145 and in the openings. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like.

In some embodiments, a photoresist is then formed and patterned on the seed layer. The photoresist may be formed by spin coating or the like and may be exposed to light for patterning. The pattern of the photoresist corresponds to the metallization patterns 146. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the metallization patterns 146.

In FIG. 1J, conductive features 22 and 24 are formed on the metallization patterns 146 and are electrically coupled to TVs 114. The conductive features 22 and 24 are formed at the top surface of the redistribution structure on the metallization patterns 146. In some embodiments, the metallization patterns 146 include UBMs. The conductive features 22 and 24 can be formed on the UBMs.

In some embodiments, the conductive features 22 and 24 may include solder balls and/or bumps, such as ball grid array (BGA) balls, C4 micro bumps, ENIG formed bumps, ENEPIG formed bumps, or the like. In some embodiments, the conductive features 22 and 24 may include a conductive material such as solder, copper, aluminum, gold, nickel, silver, palladium, tin, the like, or a combination thereof. In some embodiments, the conductive features 22 and 24 are formed by initially forming a layer of solder through methods such as evaporation, electroplating, printing, solder transfer, ball placement, or the like. Once a layer of solder has been formed on the structure, a reflow may be performed in order to shape the material into the desired bump shapes. In another embodiment, the conductive features 22 and 24 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the metal pillars. The metal cap layer may include nickel, tin, tin-lead, gold, silver, palladium, indium, nickel-palladium-gold, nickel-gold, the like, or a combination thereof and may be formed by a plating process.

The conductive features 22 and 24 will be used to bond to an additional electrical component, which may be a semiconductor substrate, a package substrate, a Printed Circuit Board (PCB), or the like (see FIG. 1L).

In FIG. 1K, components 136 are singulated between adjacent regions 130 and 132 along scribe line regions 134 to form semiconductor devices 20 comprising, among other things, a semiconductor die 108A, a component 136, and semiconductor dies 108B. The singulation may be by sawing, dicing, or the like.

As shown in FIG. 1L, the semiconductor device 20 is attached over a redistribution substrate 10, in accordance with some embodiments. The redistribution substrate 10 includes a dielectric layer 12, interconnect features 14 disposed in the dielectric layer 12, and crystalline metallization feature 16 disposed in the dielectric layer 12, in accordance with some embodiments.

In some embodiments, the dielectric layer 12 is formed using a deposition method such as plasma-enhanced chemical vapor deposition (PECVD), low-pressure chemical vapor deposition (LPCVD), or the like. Afterwards, a planarization process, such as chemical mechanical polishing (CMP) or a mechanical grinding process, may be performed to the dielectric layer 12. In some embodiments, the dielectric layer 12 may be made of a polymer material such as epoxy, polyimide, polybenzoxazole (PBO), benzocyclobutene (BCB), solder resist (SR), ABF film, and the like, in accordance with some embodiments. In some embodiments, the dielectric layer 12 is made of a photosensitive material and may undergo chemical reactions when exposed to light. In some embodiments, the dielectric layer 12 may include phospho-silicate glass (PSG), boro-silicate glass (BSG), boron-doped phospho-silicate glass (BPSG), undoped silicate glass (USG), or the like. In some embodiments of the present disclosure, the dielectric layer 12 may include an inorganic dielectric material, which may include a material selected from silicon nitride (SiNₓ), silicon oxide (SiO₂), silicon oxy-nitride (SiONₓ), silicon oxy-carbide (SiOCₓ), silicon carbide (SiC), combinations or multiple layers thereof, or the like.

In some embodiments, the interconnect features 14 may include conductive wires, vias, pillars, etc. The interconnect features 14 may be formed by a deposition method, such as chemical vapor deposition (CVD), physical vapor deposition (PVD), or atomic layer deposition (ALD), following by a patterning process. The interconnect features 14 may include Tungsten (W), aluminum (Al), copper (Cu), titanium (Ti), tantalum (Ta), titanium nitride (TiN), tantalum nitride (TaN), alloys or multiple layers thereof, or the like.

In some embodiments, the crystalline metallization feature 16 may be formed in the dielectric layer 12 and exposed from a bottom surface 12b of the dielectric layer 12. The crystalline metallization feature 16 may be formed by a deposition method, such as chemical vapor deposition (CVD), physical vapor deposition (PVD), or atomic layer deposition (ALD), following by a patterning process. The crystalline metallization feature 16 may include Tungsten (W), aluminum (Al), copper (Cu), titanium (Ti), tantalum (Ta), titanium nitride (TiN), tantalum nitride (TaN), alloys or multiple layers thereof, or the like.

In some embodiments, materials of the interconnect features 14 and the crystalline metallization feature 16 may be different. In some embodiments, the interconnect features 14 and the crystalline metallization feature 16 may include identical materials with different degrees of atomic ordering. For example, the interconnect features 14 may include amorphous metallic materials, and the crystalline metallization feature 16 may include crystalline metallic materials. In some embodiments, the crystalline metallization feature 16 may include crystalline Cu, such as Cu (111). A Cu(111) layer may include a textured structure. Cu(111) may be referred to as a “textured structure”, “textured copper”, “high textured-texture structure” or “high textured-texture copper”. A surface of the Cu(111) may be highly textured (e.g., have a high roughness). However, the roughness of the surface may be modified (e.g., by adjusting the parameter of the plating process) to be close to that of a Cu(100) layer (e.g., a non-textured structure) which may have a higher amount of random copper than a Cu(111) layer.

The metal barrier layer having a textured structure (e.g., a Cu (111) layer) may provide several advantages and benefits to the package structure. In particular, the metal barrier layer may inhibit an interdiffusion of the metallization (e.g., copper) and the metal TIM layer. The metallization may, therefore, inhibit the formation of an IMC layer at an interface between the metal barrier layer and the metal TIM layer resulting in fewer Kirkendall voids at the interface. In addition, the metal barrier layer (e.g., Cu (111) layer) may have a high thermal conductivity. As a result, the metal barrier layer having a textured structure (e.g., highly textured Cu (111) layer) may be used to improve heat dissipation efficiency in the package structure.

It should be noted that the term “textured” (or high-texture) structure” may be understood as referring to a structure (e.g., surface) containing grains oriented in a particular direction. The textured structure may be composed of columnar grains. The columnar grain textured structure may include thermally conductive materials such as gold (Au), copper (Cu), or aluminum (Al), and may include metal grain with crystal orientation of a columnar structure, e.g., copper with (111) orientation. In particular, the term “high-texture structure” may refer to a structure in which an amount of columnar grain oriented in a particular direction (e.g., Cu(111) or columnar copper with (111) orientation) is greater than 95 %, preferably 75 %, in some embodiments greater than 97 %. In contrast, the term “non-textured” may be understood as referring to a structure (e.g., surface) including a significant amount of copper other than Cu(111), such as Cu(100) or randomly arranged copper. In particular, the term “non-textured” may refer to a structure in which the amount structure may include twin boundaries, and a density of columnar grain (e.g., Cu(111) or columnar copper with (111) orientation) is 95 % or less the twin boundaries among all crystal grain boundaries may be greater than 10 μm⁻¹, in some embodiments greater than 15 μm⁻¹, in another embodiment greater than 20 μm⁻¹ .

Further, the composition and grain orientation of the crystalline Cu (e.g., Cu (111) metallization layer) may be analyzed by an electrical die sorting (EDS) process and electron backscatter diffraction (EBSD), respectively. In addition, the length, width, and thickness of the metal barrier layer may be detected from microstructure.

In some embodiments, a semiconductor device 30 is disposed over the redistribution substrate 10. In some embodiments, the semiconductor device 20 and 30 may be a logic die (e.g., central processing units (CPU), a graphics processing unit (GPU), a system-on-chip (SoC), an application processor (AP), a microcontroller, an application-specific integrated circuit (ASIC) die, or the like), a memory die (e.g., a dynamic random access memory (DRAM) die, a static random access memory (SRAM) die, a high bandwidth memory (HBM) die, or the like), a power management die (e.g., a power management integrated circuit (PMIC) die), a radio frequency (RF) die, a sensor die, a micro-electro-mechanical-system (MEMS) die, a signal processing die (e.g., a digital signal processing (DSP) die or the like), a front-end dies (e.g., an analog front-end (AFE) die), the like, or a combination thereof. In some embodiments, the semiconductor device 20 and 30 may have different functions.

After being fabricated, the semiconductor devices 20 and 30 may be placed in a desired location above the redistribution substrate 10 using, for example, a pick-and-place tool. In some embodiments, the semiconductor devices 20 and 30 are placed eccentrically with respect to the redistribution substrate 10 depending on design requirements (such as consideration of space arrangements).

In some embodiments, the semiconductor devices 20 and 30 are mounted on the redistribution substrate 10 through flip-chip bonding, although other suitable bonding techniques may also be used. As shown in FIG. 1L, the semiconductor devices 20 and 30 are placed over the redistribution substrate 10 so that their active surfaces (e.g., the surfaces facing down) faces the redistribution substrate 10. Afterwards, the semiconductor device 20 is bonded onto the interconnect feature 14 exposed at the top surface 10t of the redistribution substrate 10 via conductive features 22 and 24, and the semiconductor device 30 is bonded onto the interconnect feature 14 exposed at a top surface 10t of the redistribution substrate 10 via conductive features 32. In some embodiments, the conductive features 22, 24, and 32 may include conductive pillars, solder balls, controlled collapse chip connection (C4) bumps, micro bumps, one or more other suitable bonding structures, or a combination thereof.

Afterwards, an underfill layer 26 is provided between the redistribution substrate 10 and the semiconductor device 20 to surround the conductive features 22 and 24, in accordance with some embodiments. Similarly, an underfill layer 36 is provided between the redistribution substrate 10 and the semiconductor device 30 to surround the conductive features 32, in accordance with some embodiments. The underfill layers 26 and 36 may be configured to provide a stronger mechanical connection and a heat bridge between the redistribution substrate 10 and the semiconductor devices 20 and 30, in accordance with some embodiments of the present disclosure. In some embodiments, the underfill layers 26 and 36 include liquid epoxy, deformable gel, silicon rubber, or the like.

As shown in FIG. 1M, first connection elements 50 and second connection elements 60 are provided on the crystalline metallization features 16, in accordance with some embodiments. In some embodiments, the first connection elements 50 and the second connection elements 60 may have different structures (which will be described later). In some embodiments, the first connection elements 50 and the second connection elements 60 may be, e.g., solder balls, for subsequent bonding to another substrate. The first connection elements 50 and the second connection elements 60 may provide electrical and thermal connections between the redistribution substrate 10 and the substrate to which the redistribution substrate 10 is subsequently bonded. In some embodiments, the first connection elements 50 and the second connection elements 60 have different electrical conductivity, such as the electrical conductivity of the first connection elements 50 may be greater than the electrical conductivity of the second connection elements 60.

In FIG. 1N, a covering element 40 is provided on the redistribution substrate 10 to cover the semiconductor device 20, and the covering element 40 is in contact with thermal interface material 42 disposed over the semiconductor device 20, in accordance with some embodiments of the present disclosure. An adhesive element 44 is provided between the redistribution substrate 10 and the covering element 40, in accordance with some embodiments of the present disclosure. The adhesive element 44 may be configured to bond the covering element 40 to the redistribution substrate 10. Therefore, a semiconductor package structure 100 is formed, in accordance with some embodiments. In some embodiments, the covering element 40 surrounds the semiconductor device 20. In some embodiments, the semiconductor device 30 is exposed from the covering element 40. In some embodiments, the covering element 40 may include a stiffener ring or a lid structure.

In some embodiments, the covering element 40 is used to constrain the redistribution substrate 10 to alleviate its warpage and/or to enhance robustness of the redistribution substrate 10. In some embodiments, the material of the covering element 40 may include metal such as copper, stainless steel, stainless steel/Ni, or the like, but is not limited thereto. In some embodiments, the covering element 40 is used for heat dissipation, and the thermal interface material 42 between the covering element 40 and the semiconductor device 20 may fill the spaces between the covering element 40 and the semiconductor device 20 to ensure a maximized contact area for reducing thermal resistance, so the heat generated by the semiconductor device 20 may be effectively released by this configuration.

In some embodiments, the adhesive element 44 may be applied to the redistribution substrate 10 before installing the covering element 40 on the redistribution substrate 10. Examples of the material for the adhesive element 44 may include organic adhesive material such as epoxy, polyimide (PI), polybenzoxazole (PBO), benzo-cyclo-butene (BCB), but are not limited thereto.

As shown in FIG. 1O, the semiconductor package structure 100 is bonded to a substrate 70, in accordance with some embodiments. In some embodiments, the substrate 70 has crystalline metallization features 72 exposed on its top surface, and then the first connection elements 50 and the second connection elements 60 are bonded to the crystalline metallization features 72 to electrically connect the semiconductor package structure 100 to the substrate 70.

In some embodiments, the substrate 70 may be formed of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations thereof, or the like, may also be used. Additionally, the substrate core 222 may be a SOI substrate. Generally, an SOI substrate includes a layer of a semiconductor material such as a layer of silicon, germanium, silicon germanium, or combinations thereof. In some embodiments, the substrate 70 is an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for the substrate 70, in accordance with some embodiments.

Optionally, underfill material (not shown) may be provided between the redistribution substrate 10 and the substrate 70 to surround the first connection elements 50 and the second connection element 60. The underfill material may be any acceptable material, such as a polymer, epoxy, molding underfill, or the like. The underfill material may be formed by a capillary flow process, or may be formed by a suitable deposition method.

FIG. 1P is a top view showing some elements of the semiconductor package structure 100, in accordance with some embodiments. Some elements are omitted in FIG. 1P for simplicity. As shown in FIG. 1P, the first connection elements 50 overlap the semiconductor device 20 in a top view, and the second connection elements 60 do not overlap the semiconductor device 20 in the top view. In other words, the first connection elements 50 are disposed right under the semiconductor device 20, and the second connection elements 60 are offset from the semiconductor device 20. In some embodiments, the semiconductor device 20 has a length LA in the X direction and a width DA in the Y direction, and the redistribution substrate 10 has a length LB in the X direction and a width DB in the Y direction. In some embodiments, a ratio LA/LB is between 0 and 1, and a ratio DA/DB is also between 0 and 1. In some embodiments, the ratio LA/LB and ratio DA/DB are greater than 0. In some embodiments, the ratio LA/LB or the ratio DA/DB may be equal to 1.

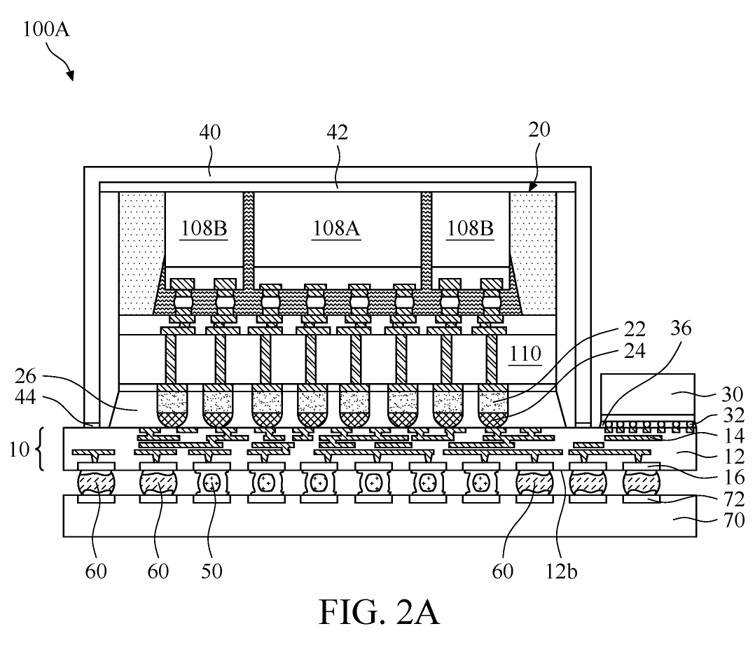

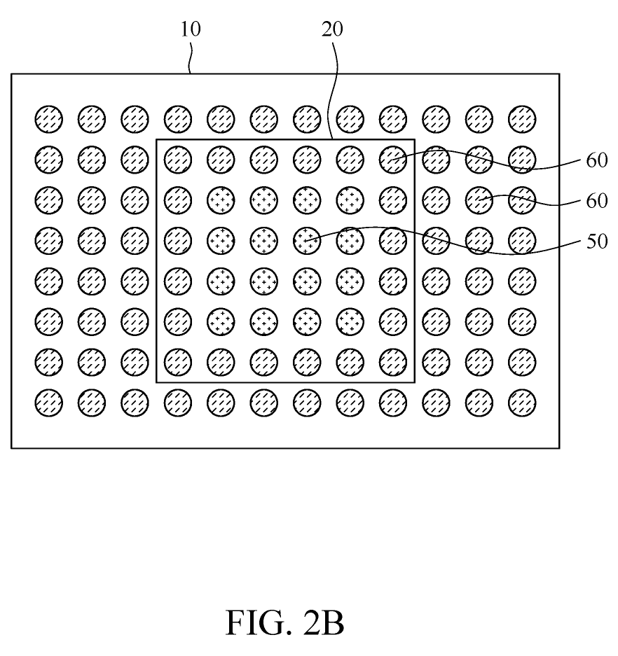

FIG. 2A is a cross-sectional view of a semiconductor package structure 100A, in accordance with some embodiments. FIG. 2B is a top view of the structure shown in FIG. 2A, in accordance with some embodiments. As shown in FIG. 2A and FIG. 2B, the first connection elements 50 and some of the second connection elements 60 are disposed under the semiconductor device 20, and another portion of the second connection elements 60 do not overlap the semiconductor device 20 in the top view, in accordance with some embodiments. In some embodiments, the second connection elements 60 disposed under the semiconductor device 20 and surround the first connection elements 50.

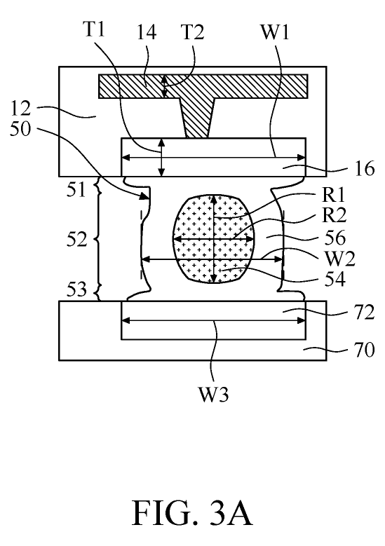

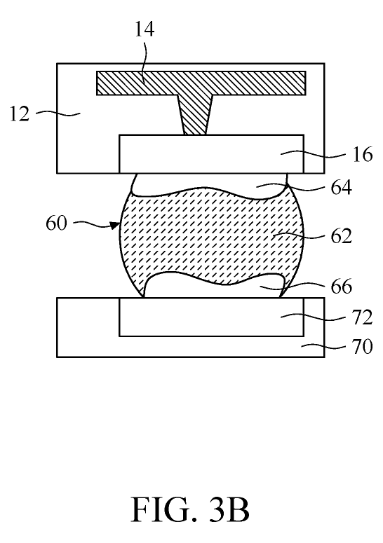

The first connection elements 50 and the second connection elements 60 may have different structures. FIG. 3A is an enlarged view of one of the first connection elements 50, in accordance with some embodiments. As shown in FIG. 3A, the first connection element 50 has a hybrid structure, which includes a core feature 54 and an intermetallic compound 56 surrounding the core feature 54, in accordance with some embodiments. In other words, the core feature 54 is embedded in the intermetallic compound 56, in accordance with some embodiments. In some embodiments, the materials of the core feature 54 and intermetallic compound 56 may be different. For example, the core feature 54 and the intermetallic compound 56 may include metal alloy with different composition. In some embodiments, the core feature 54 and the intermetallic compound 56 may include same elements with different composition. For example, the core feature 54 and the intermetallic compound 56 may include same kind of metal elements with different concentrations.

In some embodiments, the crystalline metallization features 16/72 and the core feature 54 may include a same element (such as an identical metal material) with different degrees of atomic ordering. For example, the crystalline metallization features 16/72 may include crystalline metal, and the core feature 54 may include amorphous metal. In some embodiments, the metal material of the crystalline metallization features 16/72 and the core feature 54 may include Cu, Ag, Ni, Co, Ge, Au, or the like. In some embodiments, the crystalline metallization features 16/72 may include Cu(111), and the core feature 54 may include amorphous Cu. In some embodiments, the crystalline metallization features 16/72 and the core feature 54 may form alloy with the intermetallic compound 56. In some embodiments, the crystalline metallization features 16/72 may include different materials. In some embodiments, one of the crystalline metallization features 16 or 72 may be amorphous, as long as another one being crystalline. In some embodiments, the core feature 54 and the crystalline metallization features 16/72 may include different materials, such as may include different metal materials.

Such structure may be formed by disposing metal balls over the redistribution substrate 10. The metal balls may be disposed over the redistribution substrate 10 through a stencil (not shown) having holes in specific positions. Afterwards, solder material is dispensed on the metal balls, following by performing a heating process (e.g. reflow or annealing process) to facilitate solid-state diffusion between the metal ball and the solder material. As a result, the core feature 54 may be formed from the metal balls, and the intermetallic compound 56 may be formed from the solder material adjacent to the interface between the solder material and the core feature 54, and the core feature 54 and the solder material farther from the interface remains original composition. In some embodiments, the solder material has an element (e.g. Sn), the intermetallic compound 56 includes the element (e.g. Sn), and compositions of the element in the solder material and the intermetallic compound 56 are different. For example, thecontents of Sn in the solder material may be greater than that in the intermetallic compound 56. This is because the element of the core feature 54 and the crystalline metallization features 16/72 diffuse into the solder material to form the intermetallic compound 56 to dilute the proportion of Sn. In some embodiments that the core feature 54 and the crystalline metallization features 16/72 include Cu, the intermetallic compound 56 may include an alloy of Sn and Cu, resulting the composition of Sn in the intermetallic compound being less than that in the solder material.

In some embodiments, since the crystalline metal in the crystalline metallization features 16/72 has a diffusion rate to the solder material higher than the diffusion rate of the amorphous metal to the solder material, the intermetallic compound 56 may be formed rapidly to avoid crack from generating between the crystalline metallization features 16/72 and the intermetallic compound 56 during the solid-state diffusion between them. As a result, the electrical conductivity between the crystalline metallization features 16/72, the core feature 54, and the intermetallic compound 56 may be further increased since less crack existed. The intermetallic compound 56 remains stable with no significant volume change during use. Additionally, its excellent electromigration performance makes the intermetallic compound 56 an ideal candidate to enhance the electromigration performance of the semiconductor package structure 100. Referring back to FIG. 1O, 1P, 2A, and 2B, providing the first connection element 50 under the semiconductor device 20 enhances its electrical connection rate, so high-power application may be achieved.

In some embodiments, a size R1 of the core feature 54 in a direction perpendicular to the redistribution substrate 10 (e.g. perpendicular to the bottom surface 12b) is greater than a size R2 of the core feature 54 in a direction parallel to the redistribution substrate 10. This is because when dispensing the solder material on the core feature 54, more solder material is dispensed on sides of the core feature 54 instead of between the core feature 54 and the crystalline metallization features 16/72. Afterwards, when performing reflow or annealing process, more core feature 54 is diffused into the solder material to form the intermetallic compound 56 at the side, resulting the size R2 being less than the size R1. In some embodiments, the size R1 is greater than about 5um. In some embodiments, a volume of the core feature 54 is greater than or equal to 3 % of a volume of the entire first connection element 50. In some embodiments, the crystalline metallization feature 16 may be thicker than the interconnect feature 14. For example, in some embodiments, the crystalline metallization feature 16 has a thickness T1, the interconnect feature 14 has a thickness T2, and the thickness T1 is greater than the thickness T2.

In some embodiments, the first connection element 50 includes a first region 51, a second region 52, and a third region 53. The first region 51 may be defined as the region that the first connection element 50 adjacent to the crystalline metallization feature 16, the third region 53 may be defined as the region that the first connection element 50 adjacent to the crystalline metallization feature 72, and the second region 52 is between the first region 51 and the third region 53. In some embodiments, the width of the first region 51 gradually decreased in a direction from the crystalline metallization feature 16 to the first connection element 50, and the width of the third region 53 gradually decreased in a direction from the crystalline metallization feature 72 to the first connection element 50. In the second region 52, the width of the first connection element 50 gradually increases and then gradually decreases.

In some embodiments, the crystalline metallization feature 16 has a width W1, the first connection element 50 has a width W2, and the crystalline metallization feature 72 has a width W3. In some embodiments, the width W2 may be defined as the width of the first connection element 50 of one half stand of height. That is, the width at the center point of the first connection element 50. In some embodiments, the widths W1, W2, W3 has the relationship w3 ≥ w1 ≥ w2 ≥ 50μm.

FIG. 3B is an enlarged view of the second connection element 60, in accordance with some embodiments. As shown in FIG. 3B, the second connection element 60 includes a conductive feature 62, an intermetallic compound 64 between the conductive feature 62 and the crystalline metallization feature 16, and an intermetallic compound 66 between the conductive feature 62 and the crystalline metallization feature 72, in accordance with some embodiments. In some embodiments, the conductive feature 62 includes a solder material, such as Sn and Ag or another suitable conductive material (e.g., gold), in accordance with some embodiments of the present disclosure. The conductive feature 62 may include conductive pillars, solder balls, controlled collapse chip connection (C4) bumps, micro bumps, one or more other suitable bonding structures, or a combination thereof, in accordance with some embodiments of the present disclosure. In some embodiments, the intermetallic compounds 64 and 66 may include alloy of the elements of the conductive feature 62 and the crystalline metallization features 16/72. For example, when the crystalline metallization feature 16/72 include crystalline Cu(111) and the conductive feature 62 includes Sn, the intermetallic compounds 64 and 66 may include an alloy of Cu and Sn, such as CuₓSn_{y}. In some embodiments, the x may be between 3 and 6, and y may be between 1 and 5. In some embodiments, a thickness of the intermetallic compounds 64 or 66 (i.e. the size in a direction perpendicular to the redistribution substrate 10) may be less than a thickness of the intermetallic compound 56.

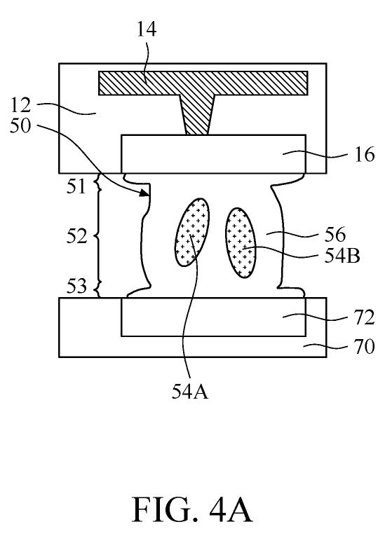

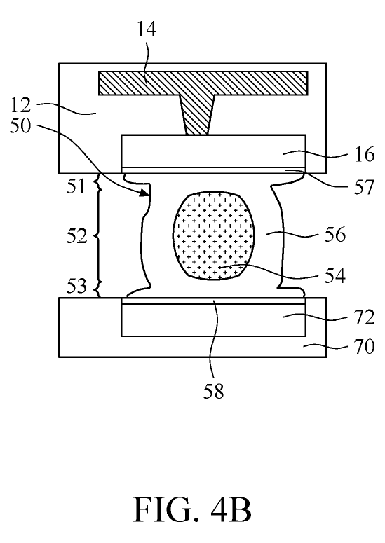

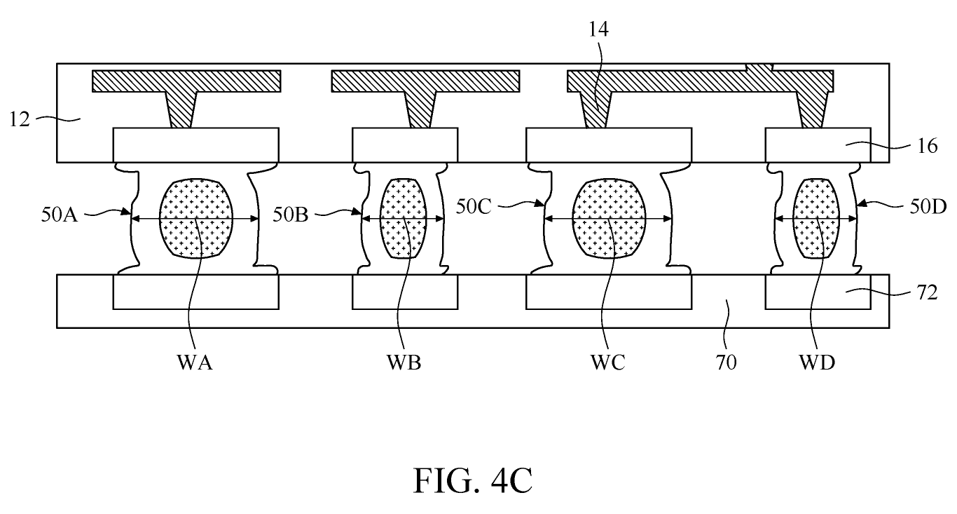

FIG. 4A is an enlarged view of the first connection element 50, in accordance with other embodiments of the present disclosure. As shown in FIG. 4A, one first connection element 50 may have multiple core features 54A and 54B inside the intermetallic compound 56. It should be noted that the core features 54A and 54B are rugby-shaped and have their long axis extending toward the crystalline metallization features 16/72. In some embodiments, the intermetallic compound 56 extends between the core features 54A and 54B. Such configuration also avoid crack from generating between the crystalline metallization features 16/72 and the intermetallic compound 56. In some embodiments, the core feature 54A is spaced apart from the core feature 54B by the intermetallic compound 56.

FIG. 4B is an enlarged view of the first connection element 50, in accordance with other embodiments of the present disclosure. As shown in FIG. 4B, conductive interface features 57 and 58 are formed between the intermetallic compound 56 and the crystalline metallization features 16 and 72, in accordance with some embodiments. In some embodiments, the conductive interface features 57 and 58 may cover the surfaces of the crystalline metallization features 16 and 72. In some embodiments, the conductive interface features 57 and 58 may include conductive material, such as metal. In some embodiments, the materials of the conductive interface features 57 and 58 and the materials of the crystalline metallization features 16 and 72 may be different. In some embodiments, the conductive interface features 57 and 58 may be formed by techniques such as organic solderability preservative (OSP), electroless nickel/electroless palladium/immersion gold (ENEPIG), electroless nickel immersion gold (ENIG), immersion Tin, Ni, Co, and the like.

FIG. 4C is an enlarged view of the first connection elements with different pitches, in accordance with other embodiments of the present disclosure. In some embodiments, the first connection elements 50A, 50B, 50C, and 50D may have widths WA, WB, WC, and WD, respectively. In some embodiments, the widths WA, WB, WC, and WD may be different from each other. For example, the width WB may be less than the widths WA and WC, and the width WD may be less than the widths WA and WC, in accordance with some embodiments. However, the present disclosure is not limited thereto. The widths of the first connection elements may be adjusted based on actual requirement.

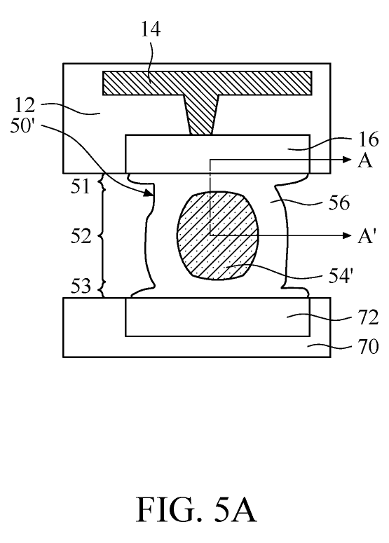

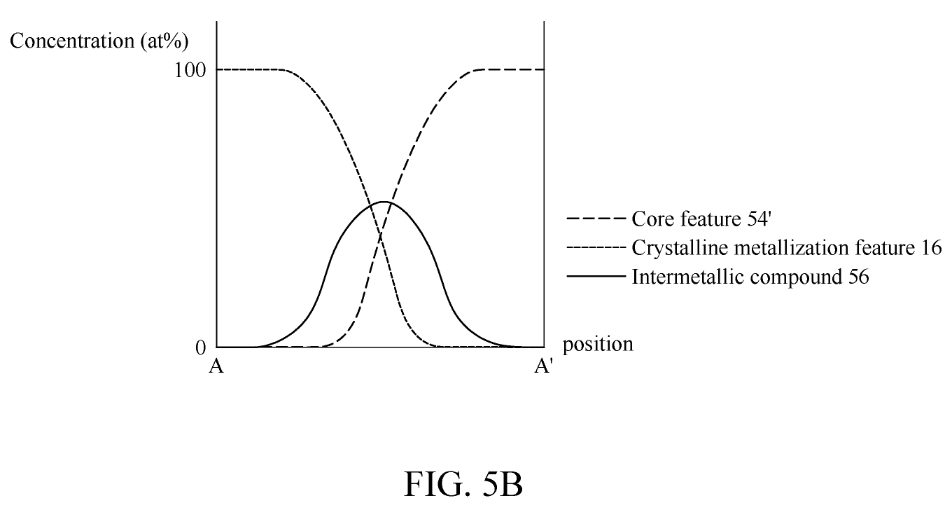

FIG. 5A is an enlarged view of the first connection element 50’, in accordance with other embodiments of the present disclosure. In some embodiments, the first connection element 50’ has a core feature 54’ and an intermetallic compound 56. In some embodiments, materials of the core feature 54’ and the crystalline metallization feature 16/72 may be different. FIG. 5B shows the material composition along the line A-A’ in FIG. 5A, in accordance with some embodiments. As shown in FIG. 5B, the composition of the crystalline metallization feature 16 gradually decreases from A to A’, the material of the core feature 54’ gradually increases from A to A’, and the material of the intermetallic compound 56 gradually increases and then decreases from A to A’. In some embodiments, the material of the core feature 54’ includes Ag, Ni, Co, Ge, Au, or the like.

In some embodiments, the composition and grain orientation of crystalline metallization feature 16 may be analyzed by energy-dispersive X-ray spectroscopy (EDS) and electron backscatter diffraction (EBSD), respectively. In some embodiments, the composition of the intermetallic compound 56 may be detected by EDS and electron probe microanalyzer (EPMA). The microstructure of the first connection element 50 may be detected by optical microscope (OM), scanning electron microscope (SEM), and transmission electron microscope (TEM).

By controlling the atomic concentration gradient of the constituent metals from the core feature 54’ to the crystalline metallization feature 16, a stable intermetallic compound 56 is generated in the intermediate region, acting as a transition zone that accommodates differences in thermal expansion and mechanical properties. This graded structure reduces stress concentrations and enhances the overall robustness of the joint, particularly under repeated thermal cycling or mechanical loads. Consequently, the occurrence of cracks is reduced, leading to greater reliability and extended service life of the device.

In summary, a semiconductor package structure having hybrid connection elements is provided. Such connection elements combine a metal core and an intermetallic compound. By leveraging a crystalline metallization feature to accelerate solid-state diffusion during the annealing process, a stable intermetallic compound may be formed. The resulting connection elements demonstrate enhanced electromigration performance and reliability to avoid void from forming. Additionally, the metallic core reduces the volume changes that typically occur during intermetallic compound formation, thereby minimizing the risk of underfill voids and improving the mechanical integrity of advanced packaging. This design is particularly suited for high-power AI and SoC applications, where smaller bump pitches and higher power densities demand superior thermal and electromigration characteristics.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

A semiconductor package structure is provided in some embodiments, which includes a redistribution substrate, a first semiconductor device disposed on a first side of the redistribution substrate, first connection elements disposed on a second side of the redistribution substrate opposite from the first side, and overlapping the first semiconductor device in a top view, and second connection elements disposed on the second side. The first semiconductor device includes a substrate disposed over the redistribution substrate, a semiconductor die disposed over the substrate, and an encapsulant disposed over the substrate. A first portion of the second connection elements is offset from the first semiconductor device in the top view, the first connection elements are surrounded by the second connection elements in the top view, and each first connection element has a higher electrical conductivity than each second connection element.

A semiconductor package structure is provided in some embodiments, which includes a redistribution substrate comprising a metallization feature, a semiconductor device disposed on the redistribution substrate, and a connection element disposed on the redistribution substrate, and overlapping the semiconductor device in a top view. The semiconductor device includes a substrate electrically connected to the redistribution substrate, a semiconductor die disposed over the substrate, and an encapsulant surrounding the semiconductor die. The connection element includes a first core feature and an intermetallic compound surrounding the first core feature and between the metallization feature and the first core feature, wherein the metallization feature and the first core feature have different degrees of atomic ordering.

A method for forming a semiconductor package structure is provided in some embodiments, which includes providing a redistribution substrate comprising first crystalline metallization features exposed from a first side, disposing a semiconductor device over a second side of the redistribution substrate opposite from the first side, disposing metal balls over the first metallization features, dispensing solder materials on the first metallization features, wherein the metal balls are surrounded by a first portion of the solder materials, and forming first connection elements comprising core features surrounded by first intermetallic compounds, including forming core features from the metal balls, and forming the first intermetallic compounds from the solder materials. The solder materials include a first element, the first intermetallic compounds comprise the first element, and compositions of the first element in the solder materials and the first intermetallic compounds are different.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure, comprising:
a redistribution substrate;
a first semiconductor device disposed on a first side of the redistribution substrate, comprising:
a substrate disposed over the redistribution substrate;
a semiconductor die disposed over the substrate; and
an encapsulant disposed over the substrate;
first connection elements disposed on a second side of the redistribution substrate opposite from the first side, and overlapping the first semiconductor device in a top view; and
second connection elements disposed on the second side, wherein a first portion of the second connection elements is offset from the first semiconductor device in the top view, the first connection elements are surrounded by the second connection elements in the top view, and each first connection element has a higher electrical conductivity than each second connection element.

2. The semiconductor package structure as claimed in claim 1, wherein a second portion of the second connection elements overlaps the first semiconductor device in the top view, and the second portion is surrounded by the first portion.

3. The semiconductor package structure as claimed in claim 1, further comprising a second semiconductor device and a covering element disposed on the first side, wherein the first semiconductor device is surrounded by the covering element, and the second semiconductor device is exposed from the covering element.

4. The semiconductor package structure as claimed in claim 1, wherein each of the first connection elements comprises a rugby-shaped core feature and an intermetallic compound surrounding the rugby-shaped core feature.

5. The semiconductor package structure as claimed in claim 4, wherein a size of the rugby-shaped core feature in a direction perpendicular to the redistribution substrate is greater than a size of the rugby-shaped core feature in a direction parallel to the redistribution substrate.

6. The semiconductor package structure as claimed in claim 1, wherein the redistribution substrate comprises:
a dielectric layer;
an interconnect feature disposed in the dielectric layer; and
a crystalline metallization feature exposed from the dielectric layer and electrically connected to the interconnect feature, wherein the interconnect feature and the crystalline metallization feature comprise different crystalline phases.

7. The semiconductor package structure as claimed in claim 6, wherein a width of the crystalline metallization feature is greater than a width of one of the first connection elements.

8. A semiconductor package structure, comprising:
a redistribution substrate comprising a metallization feature;
a semiconductor device disposed on the redistribution substrate, comprising:
a substrate electrically connected to the redistribution substrate;
a semiconductor die disposed over the substrate; and
an encapsulant surrounding the semiconductor die; and
a connection element disposed on the redistribution substrate, and overlapping the semiconductor device in a top view, comprising:
a first core feature; and
an intermetallic compound surrounding the first core feature and between the metallization feature and the first core feature, wherein the metallization feature and the first core feature have different degrees of atomic ordering.

9. The semiconductor package structure as claimed in claim 8, wherein the metallization feature is crystalline, and the first core feature is amorphous.

10. The semiconductor package structure as claimed in claim 9, wherein the metallization feature comprises Cu(111).

11. The semiconductor package structure as claimed in claim 8, wherein a volume of the first core feature is greater than or equal to 3% of a volume of the connection element.

12. The semiconductor package structure as claimed in claim 8, wherein the metallization feature and the first core feature comprise different metal elements.

13. The semiconductor package structure as claimed in claim 8, wherein the connection element further comprises a second core feature surrounded by the intermetallic compound, and the first core feature is spaced apart from the second core feature by the intermetallic compound.

14. The semiconductor package structure as claimed in claim 8, wherein the redistribution substrate further comprises a conductive interface feature disposed between the metallization feature and the connection element, wherein materials of the conductive interface feature and the metallization feature are different.

15. A method for forming a semiconductor package structure, comprising:
providing a redistribution substrate comprising first metallization features exposed from a first side;
disposing a semiconductor device over a second side of the redistribution substrate opposite from the first side;
disposing metal balls over the first metallization features;
dispensing solder materials on the first metallization features, wherein the metal balls are surrounded by a first portion of the solder materials; and
forming first connection elements comprising core features surrounded by first intermetallic compounds, comprising:
forming the core features from the metal balls; and
forming the first intermetallic compounds from the solder materials, wherein the solder materials comprise a first element, the first intermetallic compounds comprise the first element, and compositions of the first element in the solder materials and the first intermetallic compounds are different.

16. The method for forming a semiconductor package structure as claimed in claim 15, further comprising attaching the first connection elements to second metallization features of a substrate, wherein the first metallization features and the second metallization features comprise an identical metal material.

17. The method for forming a semiconductor package structure as claimed in claim 15, further comprising forming second connection elements from a second portion of the solder materials, wherein each of the second connection elements comprises a conductive feature and a second intermetallic compound disposed between the conductive feature and the first metallization features, and a thickness of the second intermetallic compounds is less than a thickness of the first intermetallic compound.

18. The method for forming a semiconductor package structure as claimed in claim 17, wherein the first connection elements are surrounded by the second connection elements.

19. The method for forming a semiconductor package structure as claimed in claim 15, further comprising providing a covering element to cover the semiconductor device.

20. The method for forming a semiconductor package structure as claimed in claim 15, wherein the first connection elements overlap the semiconductor device in a top view.
